(19) United States
(12) Patent Application Publication
(10) Pub. No.: US 2024/0072225 A1
(43) Pub. Date: Feb. 29, 2024

(54) SEMICONDUCTOR PACKAGE AND DISPLAY DEVICE

(71) Applicant: Samsung Electronics Co., Ltd., Suwon-si (KR)

(72) Inventor: Kyoung Suk YANG, Suwon-si (KR)

(21) Appl. No.: 18/198,326

(22) Filed: May 17, 2023

(30) Foreign Application Priority Data
Aug. 25, 2022 (KR) 10-2022-0106619

(51) Int. Cl. H01L 33/62; H01L 25/075; H01L 33/64

(52) U.S. Cl. CPC H01L 33/62; H01L 25/0753; H01L 33/641

(57) ABSTRACT

There is provided a semiconductor package with improved heat dissipation function. The semiconductor package comprising, a film, a wiring pattern layer disposed on the film, and including a first area and a second area surrounding the first area, a semiconductor chip disposed on the first area of the wiring pattern layer and electrically connected to the wiring pattern layer, a first insulating layer disposed on the second area of the wiring pattern layer, a first metal layer disposed on the first insulating layer and spaced apart from the semiconductor chip and a heat dissipating layer covering the semiconductor chip and made of a synthetic resin.

### CROSS-REFERENCE TO RELATED APPLICATION

This application claims priority under 35 U.S.C. § 119 from Korean Patent Application No. 10-2022-0106619, filed on Aug. 25, 2022, in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor package and a display device.

### Description of Related Art

With technological development of a display device such as a liquid crystal display device (LCD), an organic light-emitting display device (OLED), etc., large-scale and high-performance of the display device are being achieved. This requires a larger number of pixels to be present within a small area. Due to this situation, a lead pitch of a driver chip (driver IC) in a driver that controls individual pixels in the display device should be increasingly smaller, and a scheme for packaging the driver chip may be performed in various ways.

A packaging scheme mainly used in a display device field includes TCP (Tape Carrier Package), COG (Chip On Glass), COF (Chip On Film), or the like. In a high-resolution display, for example, a TV and a monitor, as an operation frequency increases, an operation load increases, causing the driver chip to be heated. Therefore, it is required to improve a heat dissipation function of a driver chip package used in the high-resolution display.

### SUMMARY

A technical purpose of the present disclosure is to provide a semiconductor package with improved heat dissipation function.

Another technical purpose of the present disclosure is to provide a display device with improved heat dissipation function.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, there is provided a semiconductor package comprising, a film, a wiring pattern layer disposed on the film, and including a first area and a second area surrounding the first area, a semiconductor chip disposed on the first area of the wiring pattern layer and electrically connected to the wiring pattern layer, a first insulating layer disposed on the second area of the wiring pattern layer, a first metal layer disposed on the first insulating layer and spaced apart from the semiconductor chip and a heat dissipating layer covering the semiconductor chip and made of a synthetic resin.

According to another aspect of the present disclosure, there is provided a semiconductor package comprising, a film, a wiring pattern layer disposed on the film, wherein the wiring pattern layer includes a first area, a second area spaced apart from the first area, and a third area surrounding the first area and the second area, a first semiconductor chip disposed on the first area of the wiring pattern layer and electrically connected to the wiring pattern layer, a second semiconductor chip disposed on the second area of the wiring pattern layer and electrically connected to the wiring pattern layer, a first insulating layer disposed on the third area of the wiring pattern layer, a first metal layer disposed on the first insulating layer and spaced apart from the first semiconductor chip and the second semiconductor chip and a heat dissipating layer covering the first semiconductor chip and the second semiconductor chip and made of a synthetic resin.

According to still another aspect of the present disclosure, there is provided a semiconductor package comprising, a film, a wiring pattern layer disposed on the film, wherein the wiring pattern layer includes a first area, a second area spaced apart from the first area, and a third area surrounding the first area and the second area, a first semiconductor chip disposed on the first area of the wiring pattern layer and electrically connected to the wiring pattern layer, a second semiconductor chip disposed on the second area of the wiring pattern layer and electrically connected to the wiring pattern layer, a first insulating layer disposed on the third area of the wiring pattern layer, a first metal layer disposed on the first insulating layer and spaced apart from the first semiconductor chip and the second semiconductor chip and a heat dissipating layer covering the first semiconductor chip and the second semiconductor chip and made of a synthetic resin.

### BRIEF DESCRIPTION OF DRAWINGS

The above and other aspects and features of the present disclosure will become more apparent by describing in detail embodiments thereof with reference to the attached drawings, in which:

FIG. 1 is a diagram for illustrating a display device according to some example embodiments of the present disclosure.

FIG. 2 is a diagram for illustrating a display device according to an example embodiment of the present disclosure.

FIG. 3 is a schematic cross-sectional view taken along A-A of FIG. 2.

FIG. 4 is an enlarged view to illustrate area R in FIG. 3.

FIG. 5 and FIG. 6 are diagrams for illustrating a semiconductor package according to an example embodiment of the present disclosure.

FIG. 7 is a diagram for illustrating a semiconductor package according to an example embodiment of the present disclosure.

FIG. 8 is a diagram for illustrating a semiconductor package according to an example embodiment of the present disclosure.

FIGS. 9 to 11 are diagrams for illustrating a semiconductor package according to an example embodiment of the present disclosure.

FIG. 12 is a cross-sectional view for illustrating a semiconductor package according to an example embodiment of the present disclosure.

FIG. 13 is a cross-sectional view for illustrating a semiconductor package according to an example embodiment of the present disclosure.

FIG. 14 is a diagram for illustrating a display device according to an example embodiment of the present disclosure.

FIG. 15 is a diagram for illustrating a display device according to an example embodiment of the present disclosure.

### DETAILED DESCRIPTIONS

For simplicity and clarity of illustration, elements in the drawings are not necessarily drawn to scale. The same reference numbers in different drawings represent the same elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may include within the spirit and scope of the present disclosure as defined by the appended claims.

A shape, a size, a ratio, an angle, a number, etc. disclosed in the drawings for illustrating embodiments of the present disclosure are exemplary, and the present disclosure is not limited thereto.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between and connected to the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. As used herein, the term “contact” refers to a direct connection (i.e., touching) unless the context indicates otherwise.

Further, as used herein, when a layer, film, region, plate, or the like may be disposed “on” or “on a top” of another layer, film, region, plate, or the like, the former may directly contact the latter or still another layer, film, region, plate, or the like may be disposed between and connected to the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between and connected to the former and the latter. Further, as used herein, when a layer, film, region, plate, or the like may be disposed “below” or “under” another layer, film, region, plate, or the like, the former may directly contact the latter or still another layer, film, region, plate, or the like may be disposed between and connected to the former and the latter. As used herein, when a layer, film, region, plate, or the like is directly disposed “below” or “under” another layer, film, region, plate, or the like, the former directly contacts the latter and still another layer, film, region, plate, or the like is not disposed between and connected to the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may be actually executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” and the like, may be used herein for ease of explanation for illustrating one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

Terms as used herein “first direction Y”, “second direction X” and “third direction Z” should not be interpreted only to have a geometric relationship in which the first direction, the second direction, and the third direction are perpendicular to each other. The “first direction Y”, “second direction X” and “third direction Z” may be interpreted to have a broader direction within a range in which components herein may work functionally.

Hereinafter, embodiments of the present disclosure will be described in detail with reference to the accompanying drawings. The same reference numerals are used for the same components in the drawings, and duplicate descriptions thereof are omitted.

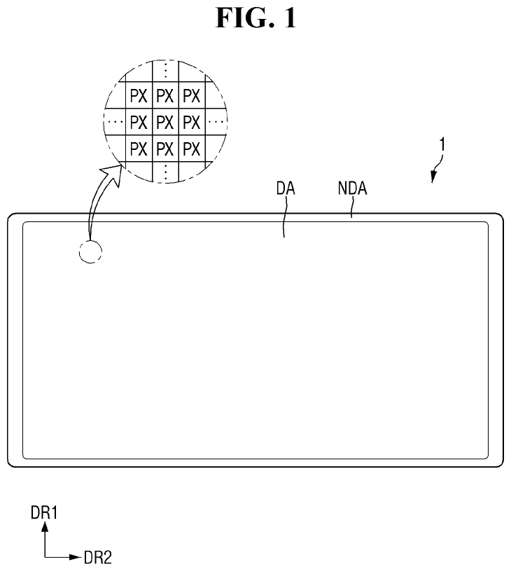

FIG. 1 is a diagram for illustrating a display device according to example embodiments of the present disclosure.

Referring to FIG. 1, a display device 1 may refer to any electronic device that provides a display screen. For example, the display device 1 may include televisions, laptops, monitors, billboards, mobile phones, smart phones, tablet PCs, personal computers, electronic watches, smart watches, watch phones, mobile communication terminals, electronic notebooks, e-books, PMPs (Portable Multimedia Players), navigation devices, game consoles, digital cameras, Internet of Things, etc., which may provide display screens.

The display device 1 may be classified in various ways based on a display scheme. For example, the display device 1 may include a liquid crystal display device (LCD), an organic light-emitting display device (OLED), an inorganic light-emitting display device (inorganic electroluminescent (EL) display), a quantum dot light-emitting display device (QED), a micro LED display device (micro-LED), a nano LED display device (nano-LED), a plasma display device (PDP), a field emission display device (FED), a cathode ray display device (CRT), an electrophoretic display device (EPD), and the like. Hereinafter, an example in which the display device 1 is embodied as the liquid crystal display device (LCD) will be described. The display device 1 may have a rectangular shape in a plan view.

The display device 1 may include short sides extending along a first direction DR1 and long sides extending along a second direction DR2. However, the present disclosure is not limited thereto. The short sides of the display device 1 may extend along the second direction DR2, and the long sides of the display device 1 may extend along the first direction DR1.

The display device 1 may include a display area DA and a non-display area NDA. The display area DA may be an active area in which an image is displayed. The display area DA may have a rectangular shape in a plan view similar to a shape of the display device 1.

The display area DA may include a plurality of pixels PX. A pixel PX may be a basic unit for displaying a screen. For example, the display area DA may include a plurality of pixels PX in the form of a pixel matrix.

The non-display area NDA may be disposed around the display area DA. The non-display area NDA may entirely or partially surround the display area DA. The display area DA may have a rectangular shape, and the non-display area NDA may be adjacent to four sides of the display area DA. The non-display area NDA may constitute a bezel of the display device 1.

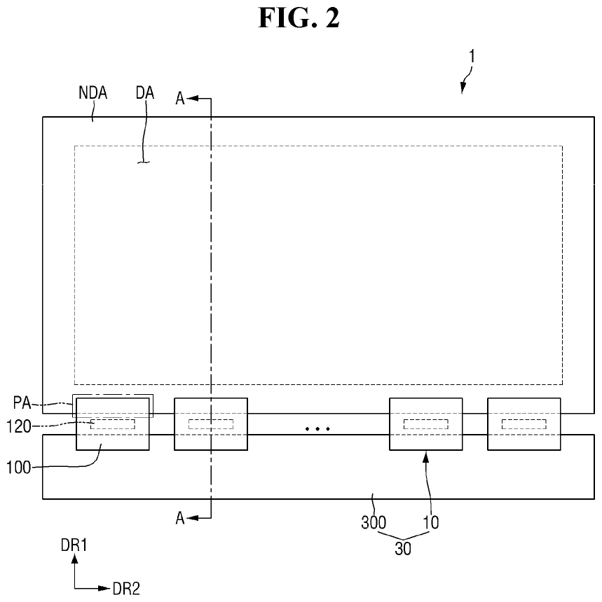

FIG. 2 is a diagram for illustrating a display device according to an example embodiment of the present disclosure.

Referring to FIG. 2, a semiconductor package 10 in which a driving circuit or a driving element for driving the display area DA may be disposed in the non-display area NDA of the display device 1. The semiconductor package 10 may be embodied as a package in a Chip On Film (COF) scheme. A plurality of semiconductor packages 10 may be disposed in a portion of the non-display area NDA adjacent to a long side of the display device 1.

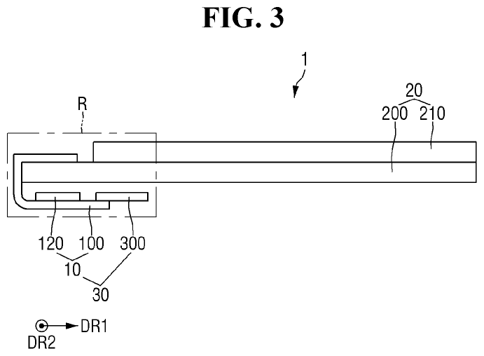

However, the present disclosure is not limited thereto. The semiconductor package 10 may be further disposed in a portion of the non-display area NDA adjacent to a short side of the display device 1. As discussed in further detail in connection with FIG. 3, the semiconductor package 10 and the printed circuit board 300 may be included in a driver 30. In example embodiments, the driver 30 may be a scan driver.

A scan driver may be disposed in a portion of the non-display area NDA adjacent to a left short side in the second direction DR2 of the display device 1. The scan driver may also be disposed in a portion of the non-display area NDA adjacent to a right short side in the second direction DR2 of the display device 1. However, the present disclosure is not limited thereto. For example, the scan driver may be disposed in a portion of the non-display area NDA adjacent to a long side of display device 1.

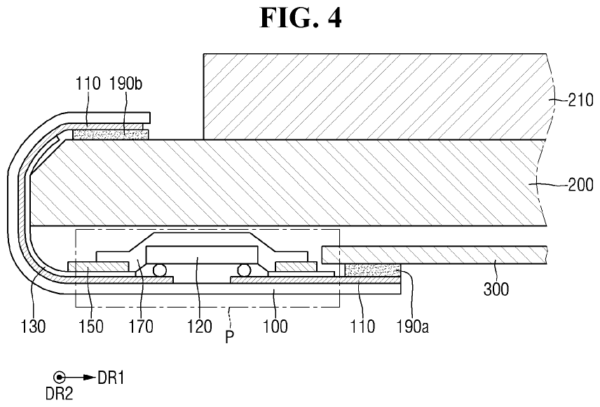

One end of a circuit pad area PA of the semiconductor package 10 may be attached to the non-display area NDA of the display device 1. The other end of the circuit pad area PA of the semiconductor package 10 may be connected to a printed circuit board 300. As discussed in further detail in connection with FIGS. 4 to 6, the semiconductor package 10 may include a film 100 and a semiconductor chip 120.

FIG. 3 is a schematic cross-sectional view taken along A-A of FIG. 2.

Referring to FIG. 3, the display device 1 may include a display panel 20 and a driver 30. The display panel 20 may include a first substrate 200 and a second substrate 210 disposed on the first substrate 200.

The first substrate 200 may include a plurality of pixels, and may include a light-emitting element disposed in each pixel. The first substrate 200 may act as a display substrate that provides light necessary for displaying an image. For example, the first substrate 200 of the display panel 20 may include a plurality of pixels (see, e.g., pixels PX of FIG. 1) arranged in a pixel matrix configured to display an image.

The second substrate 210 may be disposed so as to face the first substrate 200. For example, the second substrate 210 may act as an encapsulation substrate disposed on the first substrate 200 so as to encapsulate the light-emitting elements. The second substrate 210 may prevent damage to the light-emitting elements from air or moisture. The second substrate 210 may include a transparent plate or a transparent film. For example, the second substrate 210 may include a glass material, a quartz material, or the like.

The first substrate 200 may have a larger area than that of the second substrate 210 in a plan view. A partial area in the first direction DR1 of the first substrate 200 may not overlap the second substrate 210. The circuit pad area PA may be disposed in the partial area in the second direction DR2 of the first substrate 200 that does not overlap the second substrate 210.

The driver 30 may include the semiconductor package 10 and the printed circuit board 300, etc. In one example, FIG. 3 shows a shape in which one end of the semiconductor package 10 (see also semiconductor package 10 in FIG. 2) is bent so as to be connected to the display panel 20. The driver 30 may be connected to the first substrate 200 of the display panel 20. For example, the semiconductor package 10 may extend over an upper surface of the first substrate 200 and bend to extend below a lower surface of the first substrate 200. The driver 30 may transmit a driving signal to the pixel PX of the display panel 20. The printed circuit board 300 may be embodied as, for example, a PCB (Printed Circuit Board) or an FPCB (Flexible Printed Circuit Board).

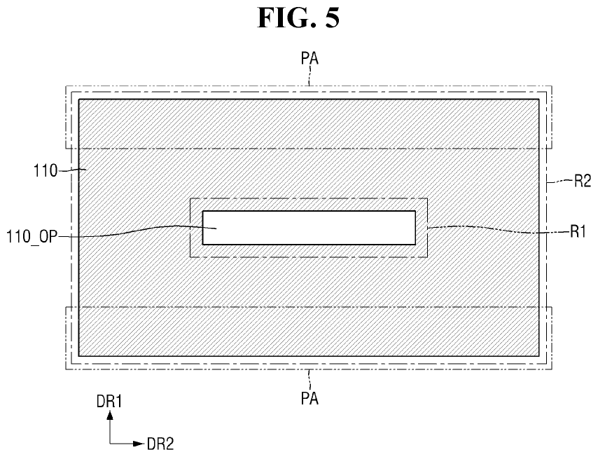

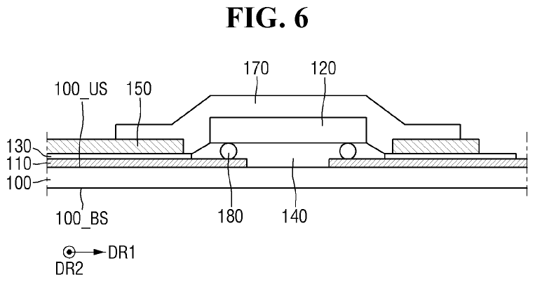

FIG. 4 is an enlarged view to illustrate area R in FIG. 3. FIG. 5 and FIG. 6 are diagrams for illustrating a semiconductor package according to example embodiments of the present disclosure. For reference, FIG. 5 is a layout diagram to illustrate a wiring pattern layer in FIG. 4. FIG. 6 is an enlarged view to illustrate area P of FIG. 4.

Referring to FIGS. 4 to 6, the semiconductor package 10 may include a film 100, a semiconductor chip 120, a wiring pattern layer 110, a first insulating layer 130, a first metal layer 150, and a heat dissipating layer 170.

A portion of the film 100 may be disposed under the display panel 20. One end of the film 100 may be disposed on a sidewall and a upper surface of the first substrate 200 of the display panel 20. The film 100 may have a upper surface 100_US on which the wiring pattern layer 110 is formed, and a bottom surface 100_BS opposite thereto. The film 100 may include an insulating synthetic resin. For example, the film 100 may include one selected from polyimide resin, acrylic resin, polyether-nitrile resin, polyether-sulfone resin, polyethylene terephthalate resin, polyethylen naphthalate resin, or polyvinyl chloride resin. The film 100 may have a thickness of 25 μm to 80 μm in a direction perpendicular to the upper and bottom surfaces 100_US and 100_BS of the film 100. However, the technical spirit of the present disclosure is not limited thereto.

The wiring pattern layer 110 may be disposed on the upper surface 100_US of the film 100. The wiring pattern layer 110 may include a first area R1 and a second area R2 surrounding the first area R1. A size of the first area R1 may be equal to or larger than a size of the semiconductor chip 120. The first area R1 may be defined as an area on which the semiconductor chip 120 is seated. An opening 110_OP may be formed in the first area R1 of the wiring pattern layer 110. The opening 110_OP is shown to have a rectangular shape. However, this is only illustrative.

The wiring pattern layer 110 may be conformally disposed along the upper surface 100_US of the film 100. One end of the wiring pattern layer 110 may be electrically connected to a pad 190a and the printed circuit board 300. For example, the wiring pattern layer 110 may contact the pad 190a, and the pad 190a may contact the printed circuit board 300. The other end of the wiring pattern layer 110 may be electrically connected to the pad 190b and the first substrate 200. For example, the wiring pattern layer 110 may contact the pad 190b, and the pad 190b may contact the first substrate 200. The wiring pattern layer 110 may transmit a signal received from the printed circuit board 300 to the semiconductor chip 120 via an electrode bump 180. The wiring pattern layer 110 may transmit a signal received from the semiconductor chip 120 to the first substrate 200 via the electrode bump 180.

The wiring pattern layer 110 may be formed by attaching a copper foil (Cu foil) as a metal layer to the upper surface 100_US of the film 100 and then patterning the copper foil in a photo process. A metal layer of the wiring pattern layer 110 may be formed using electroplating, electroless plating, casting, or lamination. The wiring pattern layer 110 may include one of copper (Cu), silver (Ag), gold (Au), nickel (Ni), tin (Sn), zinc (Zn), chromium (Cr), manganese (Mn), indium (Id), palladium (Pd), titanium (Ti), molybdenum (Mo), and platinum (Pt). The wiring pattern layer 110 may have a thickness of 6 μm to 9 μm. However, the technical idea of the present disclosure is not limited thereto.

The semiconductor chip 120 may be disposed on the first area R1 of the wiring pattern layer 110. A size of the semiconductor chip 120 may be larger than a size of the opening 110_OP of the wiring pattern layer 110. The electrode bump 180 may be disposed around the opening 110_OP. The electrode bump 180 may include, for example, a solder bump, a gold (Au) bump, or a nickel (Ni) bump. The electrode bump 180 may be disposed between the semiconductor chip 120 and the wiring pattern layer 110.

The semiconductor chip 120 may be flip-chip bond to the wiring pattern layer 110 via the electrode bump 180. The semiconductor chip 120 may be electrically connected to the wiring pattern layer 110 via the electrode bump 180. The semiconductor chip 120 may act as a driver chip that generates a signal transmitted to the display panel 20 using a signal received from the printed circuit board 300. The semiconductor chip 120 may include a gate driver integrated circuit for driving a gate line and/or a data driver integrated circuit for driving a data line. In some embodiments, the semiconductor chip 120 may further include a timing controller, a graphics RAM (GRAM), and a power driver in addition to the display driver integrated circuit.

The first insulating layer 130 may be disposed on the second area R2 of the wiring pattern layer 110. The first insulating layer 130 may be disposed around the semiconductor chip 120. The first insulating layer 130 may be disposed around the second insulating layer 140. The first insulating layer 130 may be disposed to be spaced apart from the semiconductor chip 120. The first insulating layer 130 may cover an upper surface of the wiring pattern layer 110. The first insulating layer 130 may protect the wiring pattern layer 110. The first insulating layer 130 may expose a portion of the wiring pattern layer 110 so that the wiring pattern layer 110 may be connected to the pads 190a and 190b.

The first insulating layer 130 may be made of a non-conductive material. The first insulating layer 130 may include, for example, polyurethane, polyimide, or the like. The first insulating layer 130 may have a thickness of 8 μm to 12 μm. However, the technical idea of the present disclosure is not limited thereto.

A second insulating layer 140 may be disposed on the first area R1 of the wiring pattern layer 110. The second insulating layer 140 may fill the opening 110_OP of the wiring pattern layer 110. The second insulating layer 140 may be disposed between the wiring pattern layer 110 and the semiconductor chip 120. The second insulating layer 140 may fill a space between the wiring pattern layer 110 and the semiconductor chip 120. For example, the second insulating layer 140 may contact the upper surface 100_US of the film 100, side surfaces of the wiring pattern layer 110 and the first insulating layer 130, a lower surface of the semiconductor chip 120, and side surfaces of the electrode bumps 180.

The second insulating layer 140 may be formed using a potting process. The second insulating layer 140 may include non-conductive synthetic resin. The second insulating layer 140 may include, for example, epoxy, silicone, polymethyl methacrylate (PMMA), polyethylene, polystyrene, or a combination thereof.

The first metal layer 150 may be disposed on the first insulating layer 130. The first metal layer 150 may be disposed to be spaced apart from the semiconductor chip 120. A space between the first metal layer 150 and the semiconductor chip 120 may be filled with the heat dissipating layer 170. The first metal layer 150 may have a smaller size than that of the first insulating layer 130. A length of one end of the first metal layer 150 may be smaller than that of one end of the first insulating layer 130. The first metal layer 150 may not extend beyond the first insulating layer 130. For example, the first insulating layer 130 may be disposed between the first metal layer 150 and the wiring pattern layer 110, and the first metal layer 150 may not contact the wiring pattern layer 110.

The first metal layer 150 may receive heat generated from the semiconductor chip 120 and the wiring pattern layer 110 and discharge the heat to an outside. Specifically, the heat generated from the wiring pattern layer 110 may be transferred to the first metal layer 150 through the first insulating layer 130. The heat generated from the semiconductor chip 120 may be transferred to the first metal layer 150 through the second insulating layer 140 and the heat dissipating layer 170.

The first metal layer 150 may include, for example, any one of aluminum (Al), copper (Cu), iron (Fe), or an alloy thereof. The first metal layer 150 may have a thickness of 10 μm to 80 μm. However, the technical spirit of the present disclosure is not limited thereto.

Although not shown, the first metal layer 150 may further include a coating layer protecting the first metal layer 150. The coating layer may suppress oxidation of the first metal layer 150. The coating layer may include a soft synthetic resin, for example, polyethylene terephthalate resin.

The heat dissipating layer 170 may be disposed on the semiconductor chip 120 and the first metal layer 150. The heat dissipating layer 170 may cover an upper surface of the semiconductor chip 120. In example embodiments, the heat dissipating layer 170 may contact the upper and side surfaces of the semiconductor chip 120. In some embodiments, the heat dissipating layer 170 may cover a portion of the first metal layer 150. For example, the heat dissipating layer 170 may contact the portion of the first metal layer 150. A portion of the heat dissipating layer 170 may be disposed between the first metal layer 150 and the semiconductor chip 120. The heat dissipating layer 170 may be disposed to be spaced apart from the first substrate 200.

The heat dissipating layer 170 may receive the heat generated from the semiconductor chip 120 and discharge the heat to the outside. Since the heat dissipating layer 170 is in contact with a portion of the first metal layer 150, the heat dissipating layer 170 may receive the heat from the first metal layer 150 and discharge the heat to the outside. For example, the heat generated from the wiring pattern layer 110 may be discharged to the outside via the first metal layer 150 and the heat dissipating layer 170.

The heat dissipating layer 170 may be made of a resin composition. The heat dissipating layer 170 may contain epoxy resin, epoxy resin curing agent, curing accelerator, heat dissipating filler, etc.

The epoxy resin may allow the heat dissipating layer 170 to act as an adhesive film. For example, the epoxy resin may include bisphenol A-type epoxy resin, bisphenol F-type epoxy resin, bisphenol S-type epoxy resin, or etc.

The epoxy resin curing agent may be used to cure the epoxy resin. For example, the epoxy resin curing agent may include an amide-based curing agent, a polyamine-based curing agent, an acid anhydride curing agent, a phenol novolak-type curing agent, a tertiary amine curing agent, etc. or a mixture of at least two thereof.

The curing accelerator may effectively cure the heat dissipating layer 170. For example, the curing accelerator may include a metal-based curing accelerator, an imidazole-based curing accelerator, an amine-based curing accelerator, etc. or a combination of at least two thereof.

The heat dissipating filler may improve heat dissipation characteristics of the heat dissipating layer 170. For example, the heat dissipating filler may include epoxy, acrylic, silicone or the like. In order to obtain an excellent heat dissipation effect, a thermally conductive filler may be contained in the heat dissipating layer 170. The thermally conductive filler may include alumina (Al₂O₃), boron nitride (BN), aluminum nitride (AlN), or diamond.

When a void is present between the heat dissipating layer 170 and the semiconductor chip 120 or the first metal layer 150, the heat dissipating layer 170 may be peeled off. Since the heat dissipating layer 170 according to the present disclosure is made of resin, the heat dissipating layer 170 may be formed on the semiconductor chip 120 and the first metal layer 150 without forming of the void.

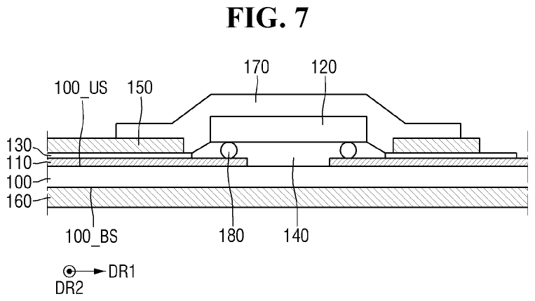

FIG. 7 is a diagram for illustrating a semiconductor package according to an example embodiment of the present disclosure. For convenience of description, the following descriptions are based on differences thereof from those as set forth above with reference to FIGS. 4 to 6.

Referring to FIG. 7, the semiconductor package 10 may further include a second metal layer 160. The second metal layer 160 may be disposed on a bottom surface 100_BS of the film 100. The second metal layer 160 may be conformally formed along the bottom surface 100_BS of the film 100. In example embodiments, the second metal layer 160 may contact the bottom surface 100_BS of the film 100. A size of the second metal layer 160 may be equal to a size of the first metal layer 150. For example, a width in the first direction DR1 of the second metal layer 160 may be equal to a width in the first direction DR1 of the first metal layer 150. However, the technical idea of the present disclosure is not limited thereto. For example, the size of the second metal layer 160 may be larger than the size of the first metal layer 150.

The second metal layer 160 may receive heat generated from the semiconductor chip 120 and the wiring pattern layer 110 and discharge the heat to the outside. Specifically, the heat generated from the semiconductor chip 120 may be transferred to the wiring pattern layer 110. The heat generated from the wiring pattern layer 110 may be transferred to the second metal layer 160 through the film 100 and then may be discharged through the second metal layer 160 to the outside. In some embodiments, a heat dissipation effect may be achieved through the first metal layer 150, the second metal layer 160, and the heat dissipating layer 170.

The second metal layer 160 may include, for example, one of aluminum (Al), copper (Cu), iron (Fe) or an alloy thereof.

Although not shown, the second metal layer 160 may further include a coating layer protecting the second metal layer 160. The coating layer may be disposed on a bottom surface of the second metal layer 160. The coating layer may prevent oxidation of the second metal layer 160. The coating layer may include a soft synthetic resin, for example, polyethylene terephthalate resin.

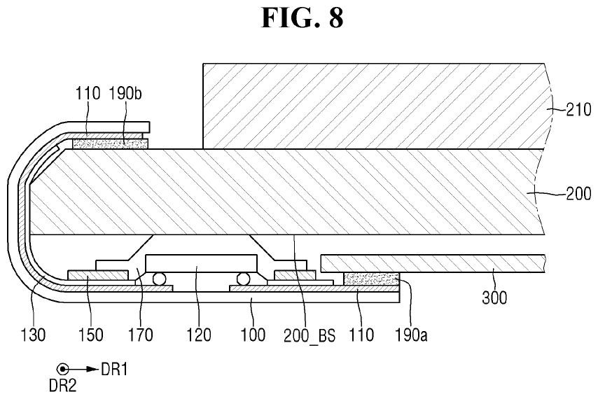

FIG. 8 is a diagram for illustrating a semiconductor package according to an example embodiment of the present disclosure. For convenience of description, the following descriptions are based on differences thereof from those as set forth above with reference to FIG. 4 to FIG. 6.

Referring to FIG. 8, the heat dissipating layer 170 may be disposed on the semiconductor chip 120, and may contact a bottom surface of the first substrate 200. The heat generated from the semiconductor chip 120 may be transferred to the heat dissipating layer 170 and then transferred to the first substrate 200. Therefore, higher heat dissipation efficiency may be achieved than that when the heat dissipating layer 170 does not contact the first substrate 200.

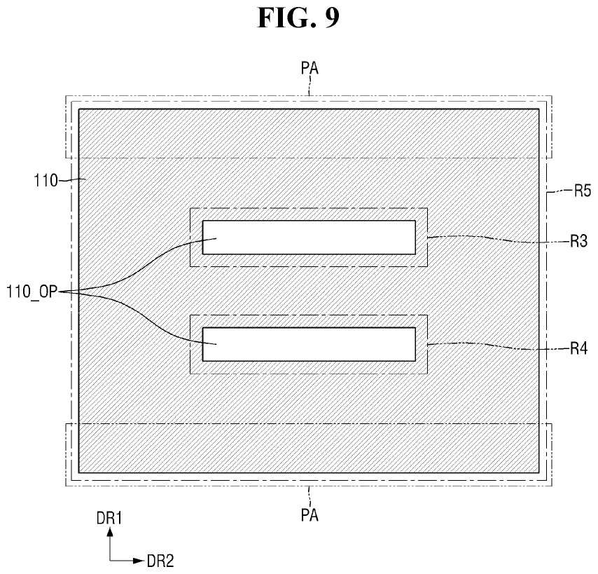

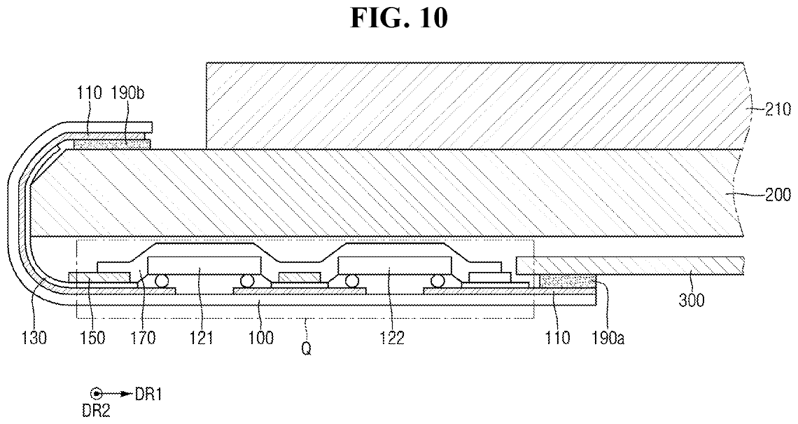

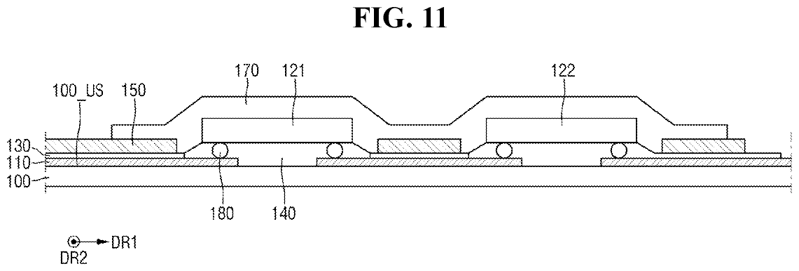

FIGS. 9 to 11 are diagrams for illustrating a semiconductor package according to an example embodiment of the present disclosure. For reference, FIG. 11 is an enlarged view to illustrate area Q of FIG. 10. For convenience of description, the following descriptions are based on differences thereof from those as set forth above with reference to FIG. 4 to FIG. 6.

Referring to FIG. 9, the wiring pattern layer 110 may be disposed on the upper surface 100_US of the film 100. The wiring pattern layer 110 may include a third area R3, a fourth area R4 spaced apart from the third area R3, and a fifth area R5 surrounding the third area R3 and the fourth area R4. An opening 110_OP may be formed in each of the third area R3 and the fourth area R4 of the wiring pattern layer 110. It is illustrated that each of the openings 110_OP has a rectangular shape. However, the present disclosure is not limited thereto.

The third area R3 may be defined as an area on which the first semiconductor chip 121 is seated. A size of the third area R3 may be equal to or larger than a size of the first semiconductor chip 121. The fourth area R4 may be defined as an area on which the second semiconductor chip 122 is seated. A size of the fourth area R4 may be equal to or larger than a size of the second semiconductor chip 122. It is illustrated that the third area R3 and the fourth area R4 are aligned with each other in the first direction DR1. However, this is only an example. In one embodiment, the third area R3 and the fourth area R4 may be aligned with each other in the second direction DR2. In another embodiment, the third area R3 and the fourth area R4 may not be aligned with each other in each of the first direction DR1 and the second direction DR2.

Referring to FIGS. 10 and 11, the first semiconductor chip 121 may be disposed on the third area R3. The second semiconductor chip 122 may be disposed on the fourth area R4. Description about each of the first semiconductor chip 121 and the second semiconductor chip 122 may be the same as the description about the semiconductor chip 120 in FIG. 4. The first semiconductor chip 121 and the second semiconductor chip 122 may be disposed on the film 100. This may be advantageous for integration.

In some embodiments, the first semiconductor chip 121 and the second semiconductor chip 122 may be identical with each other. For example, each of the first semiconductor chip 121 and the second semiconductor chip 122 may be embodied as a data driver integrated circuit or a gate driver integrated circuit.

In some embodiments, the first semiconductor chip 121 and the second semiconductor chip 122 may not be identical with each other. For example, the first semiconductor chip 121 may be embodied as a data driver integrated circuit, while the second semiconductor chip 122 may be embodied as a gate driver integrated circuit.

The heat dissipating layer 170 may be disposed on the first semiconductor chip 121, the second semiconductor chip 122, and the first metal layer 150. The heat dissipating layer 170 may cover an upper surface of each of the first semiconductor chip 121 and the second semiconductor chip 122. In some embodiments, the heat dissipating layer 170 may cover a portion of the first metal layer 150. A portion of the heat dissipating layer 170 may be disposed between the first metal layer 150 and the first semiconductor chip 121 and between the first metal layer 150 and the second semiconductor chip 122. The heat dissipating layer 170 may be disposed to be spaced apart from the first substrate 200. In some embodiments, unlike what is illustrated, the heat dissipating layer 170 may be in contact with the first substrate 200.

The heat dissipating layer 170 may receive heat generated from the first semiconductor chip 121 and the second semiconductor chip 122 and discharge the heat to the outside.

Since the heat dissipating layer 170 is in contact with the portion of the first metal layer 150, the heat dissipating layer 170 may receive the heat from the first metal layer 150 and may discharge the heat to the outside. For example, the heat generated in the wiring pattern layer 110 may be discharged to the outside via the first metal layer 150 and the heat dissipating layer 170.

When a void exists between the heat dissipating layer 170 and each of the first semiconductor chip 121, the second semiconductor chip 122 and the first metal layer 150, the heat dissipating layer 170 may be peeled off. The void may be formed more easily when there are two or more semiconductor chips 121 and 122 as shown in FIG. 11 than when there is only one semiconductor chip 120 as shown in FIG. 6. Since the heat dissipating layer 170 according to the present disclosure is made of resin, the heat dissipating layer 170 may be formed on the semiconductor chip 120 and the first metal layer 150 without forming of the void.

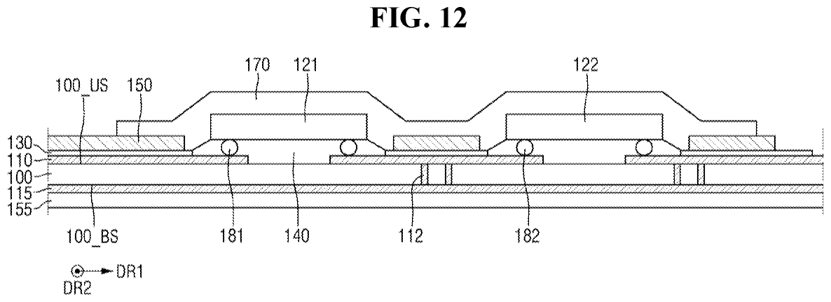

FIG. 12 is a cross-sectional view for illustrating a semiconductor package according to an example embodiment of the present disclosure. For convenience of description, the following descriptions are based on differences thereof from those as set forth above with reference to FIGS. 9 to 11.

Referring to FIG. 12, the semiconductor package 10 may further include a lower wiring pattern layer 115 and a third insulating layer 155.

The lower wiring pattern layer 115 may be disposed on the bottom surface 100_BS of the film 100. The lower wiring pattern layer 115 may be electrically connected to the wiring pattern layer 110 via a via 112. The lower wiring pattern layer 115 may transmit a signal received from the printed circuit board 300 to the first semiconductor chip 121 and/or the second semiconductor chip 122 via the wiring pattern layer 115. The lower wiring pattern layer 115 may transmit a signal received from the first semiconductor chip 121 and/or the second semiconductor chip 122 to the first substrate 200.

The lower wiring pattern layer 115 may include one of copper (Cu), silver (Ag), gold (Au), nickel (Ni), tin (Sn), zinc (Zn), chromium (Cr), manganese (Mn), indium (Id), palladium (Pd), titanium (Ti), molybdenum (Mo), and platinum (Pt). The lower wiring pattern layer 115 may include the same material as that of the wiring pattern layer 110.

The third insulating layer 155 may be disposed under the lower wiring pattern layer 115. The third insulating layer 155 may protect the lower wiring pattern layer 115. The third insulating layer 155 may cover a portion of the lower wiring pattern layer 115. The third insulating layer 155 may expose a portion of the lower wiring pattern layer 115. The third insulating layer 155 may include the same material as that of the first insulating layer 130.

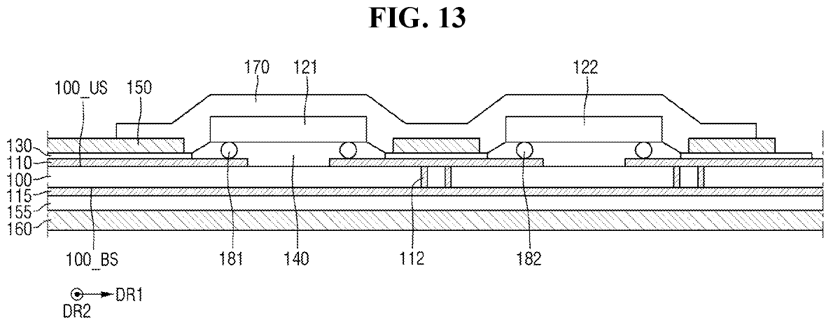

FIG. 13 is a cross-sectional view for illustrating a semiconductor package according to an example embodiment of the present disclosure. For convenience of description, the following descriptions are based on differences thereof from those as set forth above with reference to FIG. 7 and FIGS. 9 to 12.

Referring to FIGS. 12 and 13, the semiconductor package 10 may further include the second metal layer 160. The second metal layer 160 may be disposed under the third insulating layer 155. The second metal layer 160 may be conformally formed along the third insulating layer 155. A size of the second metal layer 160 may be equal to a size of the first metal layer 150. For example, a width in the first direction DR1 of the second metal layer 160 may be equal to a width in the first direction DR1 of the first metal layer 150. However, the technical idea of the present disclosure is not limited thereto. For example, the size of the second metal layer 160 may be larger than the size of the first metal layer 150.

The second metal layer 160 may receive heat generated from the first semiconductor chip 121, the second semiconductor chip 122, the wiring pattern layer 110, and the lower wiring pattern layer 115 and discharge the heat to the outside. In some embodiments, a heat dissipation effect may be achieved through the first metal layer 150, the second metal layer 160, and the heat dissipating layer 170. The second metal layer 160 may include, for example, one of aluminum (Al), copper (Cu), iron (Fe) or an alloy thereof.

Although not shown, the second metal layer 160 may further include a coating layer protecting the second metal layer 160. The coating layer may be disposed on a bottom surface of the second metal layer 160. The coating layer may prevent oxidation of the second metal layer 160. The coating layer may include a soft synthetic resin, for example, polyethylene terephthalate resin.

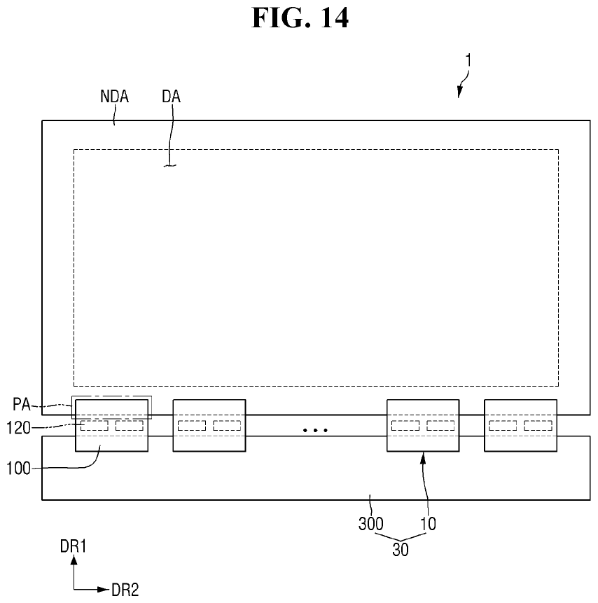

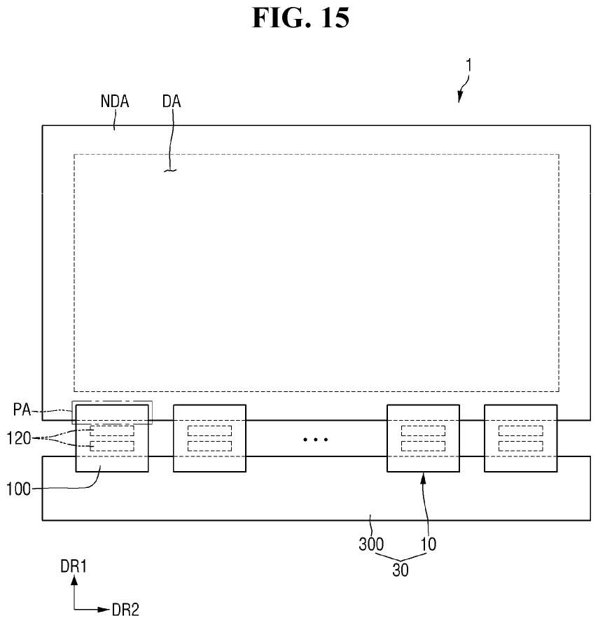

FIG. 14 is a diagram for illustrating a display device according to an example embodiment of the present disclosure. FIG. 15 is a diagram for illustrating a display device according to an example embodiment of the present disclosure.

Referring to FIGS. 14 and 15, the semiconductor package 10 may include a plurality of semiconductor chips 120. In this regard, the semiconductor chip 120 may be embodied as the semiconductor chip 120 as described with reference to FIG. 4. The plurality of semiconductor chips 120 may be spaced apart from each other in the first direction DR1 or the second direction DR2 while being disposed on one film 100. Although it is illustrated that the semiconductor chips 120 are aligned with each other in the first direction DR1 or the second direction DR2, the present disclosure is not limited thereto. For example, the semiconductor chips 120 may be randomly arranged while being disposed on the film 100.

When the plurality of semiconductor chips 120 are disposed on one film 100, this may be advantageous for integration of the driver 30. As a size of the driver 30 decreases, a size of a bezel of the display device 1 may be reduced or the bezel may be absent.

In FIG. 14 and FIG. 15, it is illustrated that the number of the semiconductor chips 120 is two. However, the technical idea of the present disclosure is not limited thereto. In some embodiments, the number of the semiconductor chips 120 may be three or larger.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor package comprising:
a film;
a wiring pattern layer disposed on the film, and including a first area and a second area surrounding the first area;
a semiconductor chip disposed on the first area of the wiring pattern layer and electrically connected to the wiring pattern layer;
a first insulating layer disposed on the second area of the wiring pattern layer;
a first metal layer disposed on the first insulating layer and spaced apart from the semiconductor chip; and
a heat dissipating layer covering the semiconductor chip and made of a synthetic resin.

2. The semiconductor package of claim 1,
wherein the first metal layer includes one of copper (Cu) and aluminum (Al), and
wherein the heat dissipating layer includes one of epoxy resin, a silicon (Si) compound, and alumina (Al₂O₃).

3. The semiconductor package of claim 2, wherein the semiconductor package further comprises a second metal layer disposed on a bottom surface of the film.

4. The semiconductor package of claim 1, wherein the semiconductor package further comprises a second insulating layer disposed between the semiconductor chip and the first area of the wiring pattern layer.

5. The semiconductor package of claim 4,
wherein the wiring pattern layer includes an opening overlapping the semiconductor chip, and
wherein the opening is filled with the second insulating layer.

6. The semiconductor package of claim 4,
wherein the semiconductor package further comprises an electrode bump disposed in the second insulating layer, and
wherein the electrode bump electrically connects the semiconductor chip and the wiring pattern layer to each other.

7. The semiconductor package of claim 1, wherein the heat dissipating layer is in contact with a display panel.

8. The semiconductor package of claim 1, wherein the heat dissipating layer covers a portion of the first metal layer.

9. The semiconductor package of claim 1, wherein the first metal layer does not contact the wiring pattern layer.

10. A semiconductor package comprising:
a film;
a wiring pattern layer disposed on the film, wherein the wiring pattern layer includes a first area, a second area spaced apart from the first area, and a third area surrounding the first area and the second area;
a first semiconductor chip disposed on the first area of the wiring pattern layer and electrically connected to the wiring pattern layer;
a second semiconductor chip disposed on the second area of the wiring pattern layer and electrically connected to the wiring pattern layer;
a first insulating layer disposed on the third area of the wiring pattern layer;
a first metal layer disposed on the first insulating layer and spaced apart from the first semiconductor chip and the second semiconductor chip; and
a heat dissipating layer covering the first semiconductor chip and the second semiconductor chip and made of a synthetic resin.

11. The semiconductor package of claim 10, wherein the semiconductor package further comprises a second metal layer disposed on a bottom surface of the film.

12. The semiconductor package of claim 10,
wherein the first metal layer includes one of copper (Cu) and aluminum (Al), and
wherein the heat dissipating layer includes one of epoxy resin, a silicon (Si) compound, and alumina (Al₂O₃).

13. The semiconductor package of claim 10,
wherein the first semiconductor chip includes a gate driver integrated circuit, and
wherein the second semiconductor chip includes a data driver integrated circuit.

14. The semiconductor package of claim 10, wherein the semiconductor package further comprises a lower wiring pattern layer disposed on a bottom surface of the film, and connected to the wiring pattern layer.

15. The semiconductor package of claim 10, wherein the semiconductor package further comprises a second insulating layer disposed between the first semiconductor chip and the first area of the wiring pattern layer, and between the second semiconductor chip and the second area of the wiring pattern layer.

16. The semiconductor package of claim 15,
wherein the wiring pattern layer has a first opening, and the first opening overlaps the first semiconductor chip,
wherein the wiring pattern layer has a second opening, and the second opening overlaps the second semiconductor chip, and
wherein each of the first opening and the second opening is filled with the second insulating layer.

17. The semiconductor package of claim 15, wherein the semiconductor package further comprises:
a first electrode bump disposed in the second insulating layer, and electrically connecting the first semiconductor chip and the wiring pattern layer to each other; and
a second electrode bump disposed in the second insulating layer, and electrically connecting the second semiconductor chip and the wiring pattern layer to each other.

18. The semiconductor package of claim 10, wherein the heat dissipating layer is in contact with a display panel.

19. The semiconductor package of claim 10, wherein the heat dissipating layer covers a portion of the first metal layer.

20. A display device comprising:
a display panel including a pixel matrix configured to display an image; and
a driver including a semiconductor package configured to drive the display panel,
wherein the semiconductor package includes:
a film;
a wiring pattern layer disposed on the film, and including a first area and a second area surrounding the first area;
a semiconductor chip disposed on the first area of the wiring pattern layer and electrically connected to the wiring pattern layer;
a first insulating layer disposed on the second area of the wiring pattern layer;
a first metal layer disposed on the first insulating layer and spaced apart from the semiconductor chip;
a second metal layer disposed on a bottom surface of the film; and
a heat dissipating layer covering the semiconductor chip and a portion of the first metal layer and made of a synthetic resin,
wherein the first metal layer includes one of copper (Cu) and aluminum (Al), and
wherein the heat dissipating layer includes one of epoxy resin, a silicon (Si) compound, and alumina (Al₂O₃).
